(19) United States
(12) Patent Application Publication
(10) Pub. No.: US 2012/0206172 A1
(43) Pub. Date: Aug. 16, 2012

(54) INTERNAL POWER SUPPLY VOLTAGE GENERATION CIRCUIT

(76) Inventor: Masakazu Sugiura, Chiba-shi (JP)

(21) Appl. No.: 13/371,998

(22) Filed: Feb. 13, 2012

(30) Foreign Application Priority Data
Feb. 16, 2011 (JP) 2011-031296

(51) Int. Cl. H03K 3/027

(52) U.S. Cl. 327/109

(57) ABSTRACT

Provided is an internal power supply voltage generation circuit, with which a through current that flows during the operation of a logic circuit can be prevented from being excessive due to fluctuations in threshold voltage of a P-type transistor and an N-type transistor forming the logic circuit, and current consumption can be suppressed. Provided is an internal power supply voltage generation circuit for generating an internal power supply voltage at an internal power supply terminal and supplying the internal power supply voltage to a logic circuit, the internal power supply voltage generation circuit including a transistor having a source follower configuration for outputting a voltage applied to a gate thereof. A value of the internal power supply voltage is given based on the sum of an absolute value of a threshold voltage of an N-type transistor and an absolute value of a threshold voltage of a P-type transistor.

### RELATED APPLICATIONS

This application claims priority under 35 U.S.C. §119 to Japanese Patent Application No. 2011-031296 filed on Feb. 16, 2011, the entire content of which is hereby incorporated by reference.

### BACKGROUND OF THE INVENTION

1. Field of the Invention

The present invention relates to an internal power supply voltage generation circuit for generating an internal power supply voltage at an internal power supply terminal and supplying the internal power supply voltage to a logic circuit.

2. Description of the Related Art

A conventional internal power supply voltage generation circuit is described. FIG. 7 is a block diagram illustrating the conventional internal power supply voltage generation circuit.

A saturation-connected transistor 701 having a source follower configuration decreases a power supply voltage VDD applied to a gate thereof to an internal power supply voltage DVDD, and outputs the internal power supply voltage DVDD. With the internal power supply voltage DVDD and a ground voltage VSS, a logic circuit 702 operates.

The logic circuit 702 is a circuit that outputs a signal of High level or Low level and is, for example, an oscillation circuit or a counter for counting the number of input pulses.

During the operation of the logic circuit 702, the internal power supply voltage DVDD is maintained to a constant value, and hence the logic circuit 702 can operate stably.

During the operation of the logic circuit 702, current consumption greatly depends on a through current, specifically the magnitude of the power supply voltage of the logic circuit 702. When the power supply voltage for the logic circuit 702 decreases from the power supply voltage VDD to the internal power supply voltage DVDD, the through current that flows during the operation of the logic circuit 702 decreases correspondingly (see, for example, Japanese Patent Application Laid-open No. Hei 08-018339).

In the conventional technology, however, the internal power supply voltage DVDD has no correlation to threshold voltages of a P-type transistor and an N-type transistor forming the logic circuit 702, and hence, depending on fluctuations in threshold voltage of the transistors, the through current that flows during the operation of the logic circuit 702 fluctuates.

The through current of the logic circuit 702 is generated when the P-type transistor and the N-type transistor forming the logic circuit 702 are turned ON at the same time. When the power supply voltage is larger than the sum of absolute values of the threshold voltages of the P-type transistor and the N-type transistor forming the logic circuit 702, an overdrive voltage applied to each of the transistors increases, and hence the through current increases. In other words, as the absolute value of the threshold voltage is lower, the overdrive voltage applied to the transistor becomes larger, and hence the through current increases.

Accordingly, there has been a problem that, if the absolute values of the threshold voltages of the P-type transistor and the N-type transistor forming the logic circuit 702 fluctuate to be lower, the through current that flows during the operation of the logic circuit 702 becomes excessive and current consumption increases.

In other words, the through current that flows during the operation of the logic circuit 702 to which the internal power supply voltage DVDD is supplied depends on the threshold voltages of the P-type transistor and the N-type transistor forming the logic circuit, with the result that the current consumption increases.

### SUMMARY OF THE INVENTION

The present invention has been made for solving the above-mentioned problem, and realizes an internal power supply voltage generation circuit with which a through current that flows during the operation of a logic circuit to which an internal power supply voltage is supplied can be prevented from being excessive due to fluctuations in threshold voltage of a P-type transistor and an N-type transistor forming the logic circuit.

According to the present invention, there is provided an internal power supply voltage generation circuit including: an output transistor for generating an output voltage which follows a voltage applied to an input of the output transistor; and a voltage source provided to the input of the output transistor, in which an internal power supply voltage is given based on a sum of an absolute value of a threshold voltage of an N-type transistor and an absolute value of a threshold voltage of a P-type transistor, the N-type transistor and the P-type transistor forming the voltage source.

According to the internal power supply voltage generation circuit of the present invention, the through current that flows during the operation of the logic circuit to which the internal power supply voltage is supplied can be prevented from being excessive due to fluctuations in threshold voltage of the P-type transistor and the N-type transistor forming the logic circuit, and current consumption can be suppressed.

### BRIEF DESCRIPTION OF THE DRAWINGS

In the accompanying drawings:

FIG. 1 is a block diagram illustrating an internal power supply voltage generation circuit according to a first embodiment of the present invention;

FIG. 2 is a block diagram illustrating the internal power supply voltage generation circuit according to the first embodiment of the present invention;

FIG. 3 is a block diagram illustrating the internal power supply voltage generation circuit according to the first embodiment of the present invention;

FIG. 4 is a block diagram illustrating an internal power supply voltage generation circuit according to a second embodiment of the present invention;

FIG. 5 is a block diagram illustrating the internal power supply voltage generation circuit according to the second embodiment of the present invention;

FIG. 6 is a block diagram illustrating the internal power supply voltage generation circuit according to the second embodiment of the present invention; and

FIG. 7 is a block diagram illustrating a conventional internal power supply voltage generation circuit.

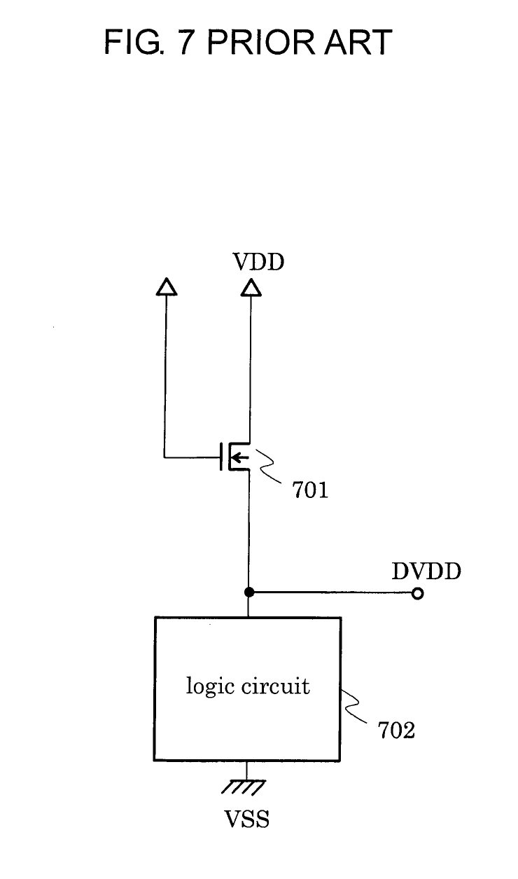

### DETAILED DESCRIPTION OF THE PREFERRED EMBODIMENTS

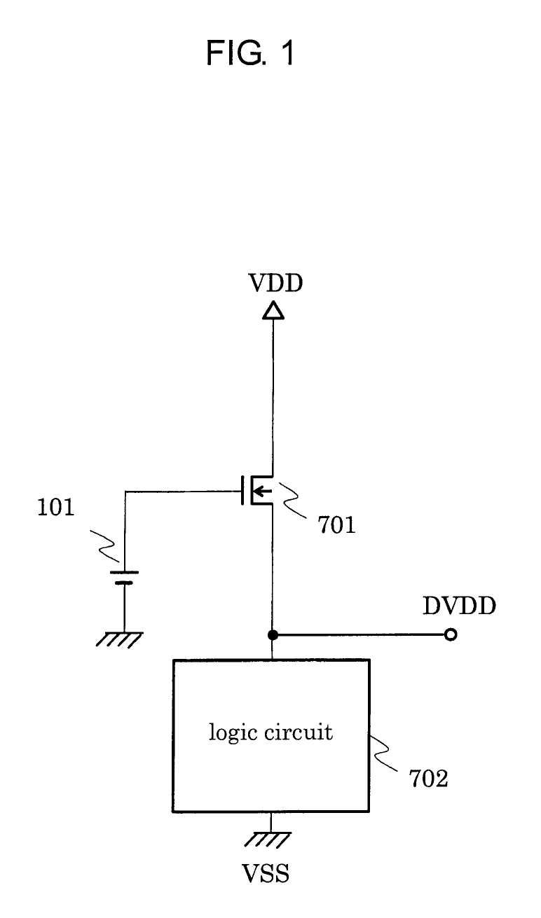

FIG. 1 is a block diagram illustrating an internal power supply voltage generation circuit according to a first embodiment of the present invention.

The internal power supply voltage generation circuit according to the first embodiment includes an N-type MOS transistor 701 and a voltage source 101.

The transistor 701 has a drain connected to a power supply terminal and a source connected to an internal power supply voltage output terminal (internal power supply voltage DVDD). The voltage source 101 is connected to a gate of the transistor 701. To the internal power supply voltage output terminal (internal power supply voltage DVDD), a logic circuit 702 as a load is connected.

Hereinafter, an operation of the internal power supply voltage generation circuit according to the first embodiment of the present invention is described.

The transistor 701 having a source follower configuration decreases a voltage of the voltage source 101 applied to a gate thereof to the internal power supply voltage DVDD, and outputs the internal power supply voltage DVDD. In other words, the transistor 701 outputs the voltage of the voltage source 101 applied to the gate thereof, which is an input terminal, to a source thereof as the internal power supply voltage DVDD that follows the voltage of the voltage source 101. With the internal power supply voltage DVDD and a ground voltage VSS, the logic circuit 702 operates.

An appropriate value of the voltage of the voltage source 101 is applied to the gate of the transistor 701 to control the internal power supply voltage DVDD to be the sum of absolute values of threshold voltages of an N-type transistor and a P-type transistor forming the logic circuit 702. As described above, a through current that flows during the operation of the logic circuit 702 is generated when the P-type transistor and the N-type transistor forming the logic circuit 702 are turned ON at the same time. The internal power supply voltage DVDD, which is a power supply voltage for the logic circuit 702, is controlled to be the sum of the absolute values of the threshold voltages of the N-type transistor and the P-type transistor forming the logic circuit 702, and hence an overdrive voltage of each of the N-type transistor and the P-type transistor forming the logic circuit 702 can be suppressed to be lower. That is, it is possible to provide an internal power supply voltage generation circuit with which the through current that flows during the operation of the logic circuit 702 can be prevented from being excessive due to fluctuations in threshold voltage of the N-type transistor and the P-type transistor forming the logic circuit 702, and current consumption can be suppressed.

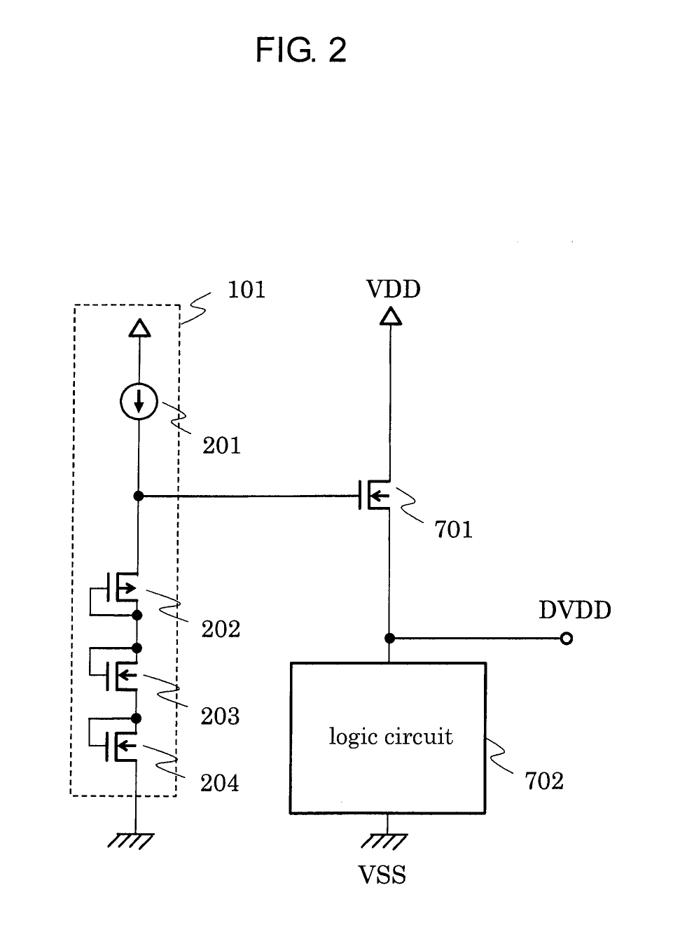

The voltage source 101 is formed of, for example, a circuit as illustrated in FIG. 2 in which N-type transistors 203 and 204 and a P-type transistor 202 are saturation-connected. The respective transistors in the voltage source 101 are formed in the same manufacturing process as the transistors forming the logic circuit 702. A current source 201 supplies a small current. Accordingly, at the gate of the transistor 701, the sum of twice an absolute value of a threshold voltage of the N-type transistors and an absolute value of a threshold voltage of the P-type transistor is generated. The internal power supply voltage DVDD is a value obtained by subtracting a gate-source voltage of the transistor 701, namely the threshold voltage of the N-type transistor, from the gate voltage of the transistor 701. Thus, the internal power supply voltage DVDD is given as the sum of the absolute values of the threshold voltages of the N-type transistor and the P-type transistor.

In the above description, in the voltage source 101 illustrated in FIG. 2, the respective transistors are formed in the same manufacturing process as the transistors forming the logic circuit 702. Alternatively, for example, the transistor 204 and the transistor 701 may be formed in different manufacturing processes from the logic circuit 702 as long as the transistor 204 and the transistor 701 are formed in the same manufacturing process.

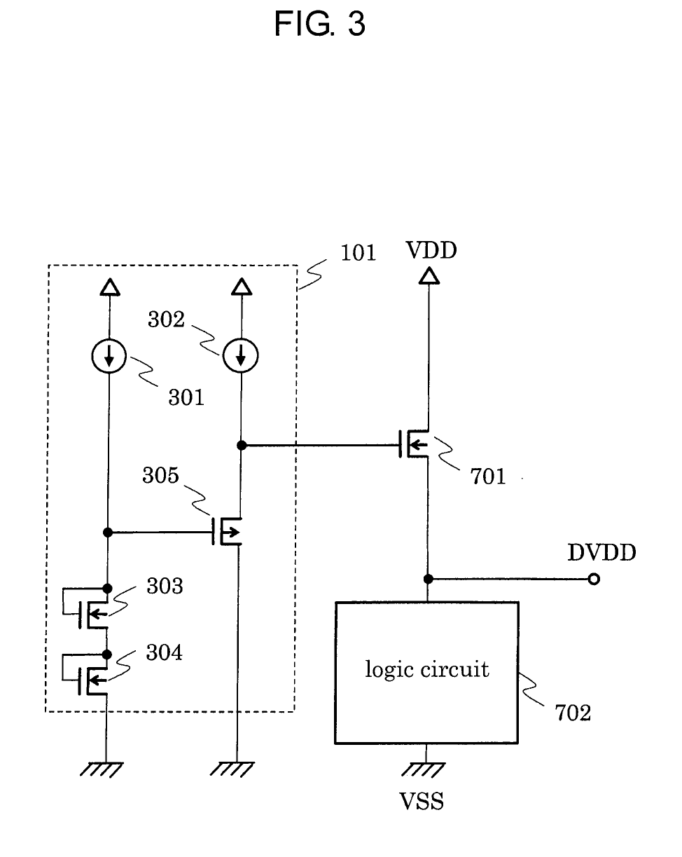

The voltage source 101 may also be formed of, for example, a circuit illustrated in FIG. 3. Respective transistors 303, 304, and 305 in a voltage source 101 illustrated in FIG. 3 are formed in the same manufacturing process as the transistors forming the logic circuit 702. Current sources 301 and 302 supply a small current. Accordingly, at the gate of the transistor 701, the sum of twice the absolute value of the threshold voltage of the N-type transistors and the absolute value of the threshold voltage of the P-type transistor is generated. The internal power supply voltage DVDD is a value obtained by subtracting the gate-source voltage of the transistor 701, namely the threshold voltage of the N-type transistor, from the gate voltage of the transistor 701. Consequently, the internal power supply voltage DVDD is given as the sum of the absolute values of the threshold voltages of the N-type transistor and the P-type transistor.

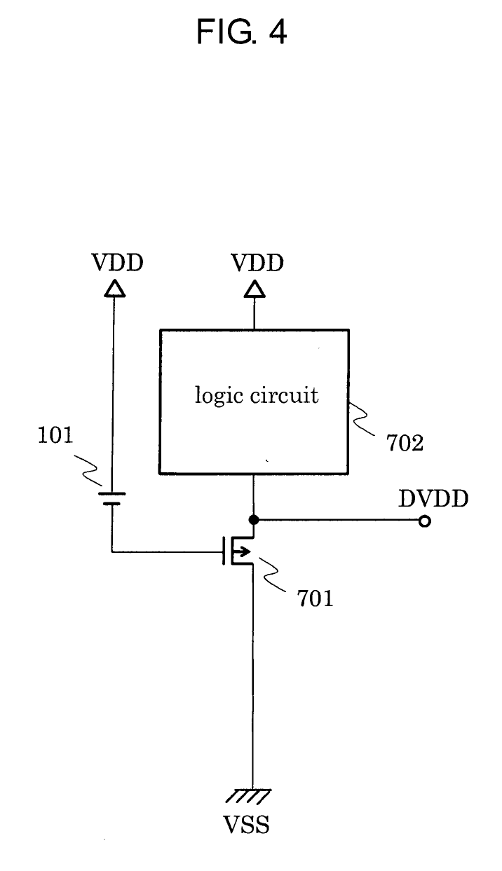

FIG. 4 is a block diagram illustrating an internal power supply voltage generation circuit according to a second embodiment of the present invention. The differences from the internal power supply voltage generation circuit of FIG. 1 reside in that the transistor 701 is replaced with a P-type transistor, that the logic circuit 702 is provided between the power supply terminal (voltage VDD) and the source of the transistor 701, and that the voltage source 101 is provided between the power supply terminal (voltage VDD) and the gate of the transistor 701.

Hereinafter, an operation of the internal power supply voltage generation circuit according to the second embodiment is described.

An appropriate value of the voltage of the voltage source 101 is applied to the gate of the transistor 701 to control the internal power supply voltage DVDD to be the sum of absolute values of threshold voltages of an N-type transistor and a P-type transistor forming the logic circuit 702. As described above, the through current that flows during the operation of the logic circuit 702 is generated when the P-type transistor and the N-type transistor forming the logic circuit 702 are turned ON at the same time. A difference voltage between the voltage VDD, which is a power supply voltage for the logic circuit 702, and the internal power supply voltage DVDD is controlled to be the sum of the absolute values of the threshold voltages of the N-type transistor and the P-type transistor forming the logic circuit 702, and hence an overdrive voltage of each of the N-type transistor and the P-type transistor forming the logic circuit 702 can be suppressed to be lower. That is, it is possible to provide an internal power supply voltage generation circuit with which the through current that flows during the operation of the logic circuit 702 can be prevented from being excessive due to fluctuations in threshold voltage of the N-type transistor and the P-type transistor forming the logic circuit 702, and current consumption can be suppressed.

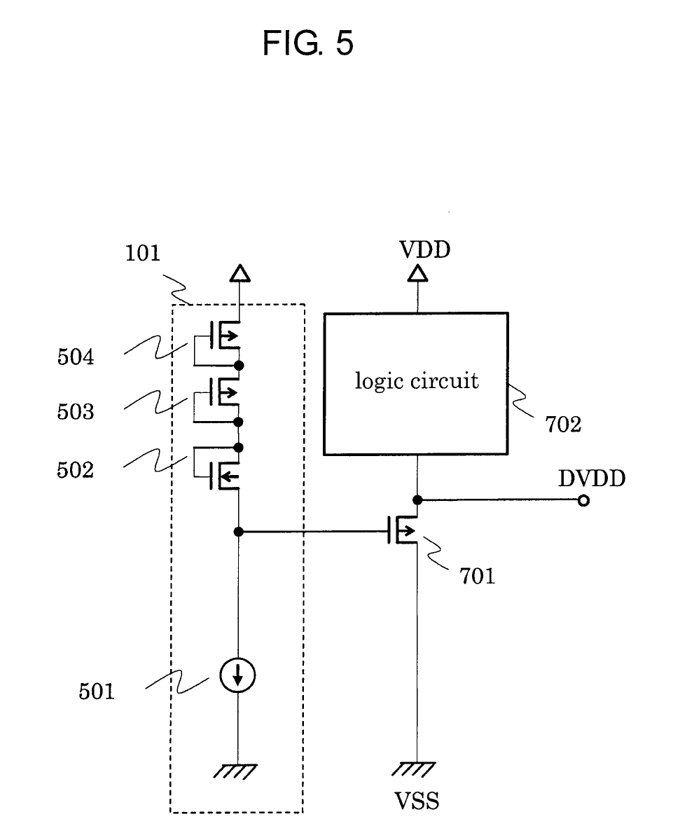

The voltage source 101 is formed of, for example, a circuit as illustrated in FIG. 5 in which an N-type transistor 502 and P-type transistors 503 and 504 are saturation-connected. The respective transistors in the voltage source 101 illustrated in FIG. 5 are formed in the same manufacturing process as the transistors forming the logic circuit 702. A current source 501 supplies a small current. Accordingly, a difference voltage between the voltage VDD and the gate voltage of the transistor 701 is the sum of an absolute value of a threshold value of the N-type transistor and twice an absolute value of a threshold voltage of the P-type transistors. The difference voltage between the voltage VDD and the internal power supply voltage DVDD is a value obtained by adding a gate-source voltage of the transistor 701, namely the threshold voltage of the P-type transistor, to the gate voltage of the transistor 701. Consequently, the difference voltage between the voltage VDD and the internal power supply voltage DVDD is given as the sum of the absolute values of the threshold voltages of the N-type transistor and the P-type transistor.

In the above description, in the voltage source 101 illustrated in FIG. 5, the respective transistors are formed in the same manufacturing process as the transistors forming the logic circuit 702. Alternatively, for example, the transistor 504 and the transistor 701 may be formed in different manufacturing processes from the logic circuit 702 as long as the transistor 504 and the transistor 701 are formed in the same manufacturing process.

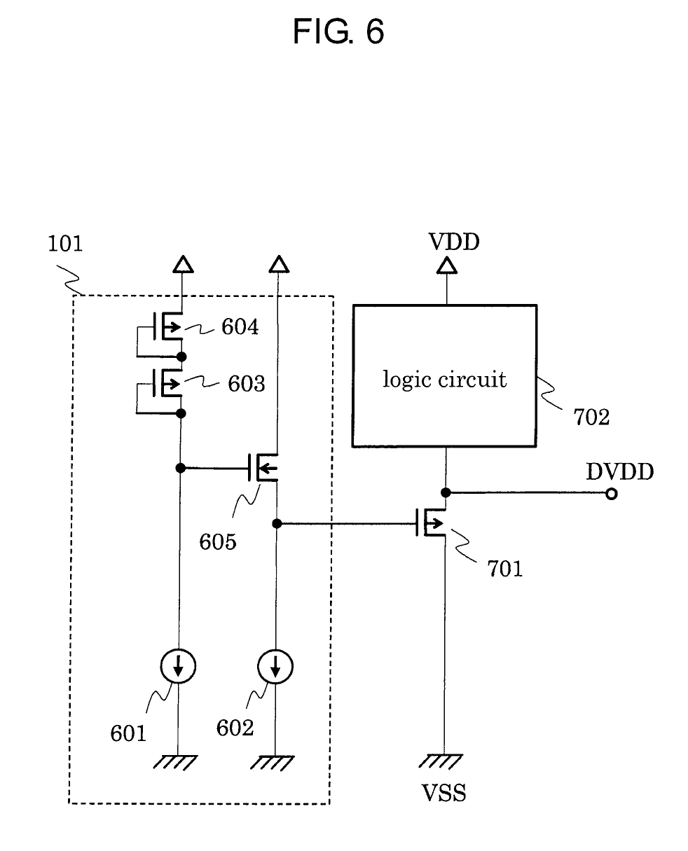

The voltage source 101 may also be formed of, for example, a circuit illustrated in FIG. 6. Respective transistors 603, 604, and 605 in a voltage source 101 illustrated in FIG. 6 are formed in the same manufacturing process as the transistors forming the logic circuit 702. Current sources 601 and 602 supply a small current. Accordingly, the difference voltage between the voltage VDD and the gate voltage of the transistor 701 is the sum of the absolute value of the threshold voltage of the N-type transistor and twice the absolute value of the threshold voltage of the P-type transistors.

The difference voltage between the voltage VDD and the internal power supply voltage DVDD is a value obtained by adding the gate-source voltage of the transistor 701, namely the threshold voltage of the P-type transistor, to the gate voltage of the transistor 701. Consequently, the difference voltage between the voltage VDD and the internal power supply voltage DVDD is given as the sum of the absolute values of the threshold voltages of the N-type transistor and the P-type transistor.

According to the internal power supply voltage generation circuit of this embodiment having the configuration described above, the through current that flows during the logic circuit to which the internal power supply voltage is supplied can be prevented from being excessive due to fluctuations in threshold voltage of the P-type transistor and the N-type transistor forming the logic circuit, and current consumption can be suppressed.

Note that, the internal power supply voltage generation circuit of this embodiment described above is not provided with a current source for supplying a current to the transistor 701 all the time, but may be provided with the current source. If the current to be supplied to the transistor 701 all the time can be replaced with a leakage current of the logic circuit 702, then it is not necessary to provide the current source.

Further, in the above description, the transistor 701 is a MOS transistor, but the transistor 701 may also be another kind of transistor such as a bipolar transistor. It should be understood that the same effect can be obtained as long as the transistor 701 outputs the internal power supply voltage DVDD that follows an input voltage and the voltage between its input and output terminals is cancelled with the threshold value of the transistor forming the voltage source 101. For example, in the case of MOS transistors, there is an advantage of low consumption because no gate current basically flows. Alternatively, for example, in the case of bipolar transistors, there is an advantage of increased speed because a higher speed operation is possible as compared to the MOS transistors.

Further, the voltage source 101 described above has the configuration illustrated in FIG. 2, 3, 5, or 6, but the voltage source 101 is not limited thereto as long as the same function is provided.

Further, in the internal power supply voltage generation circuit according to this embodiment, fluctuations in threshold voltage due to a back gate voltage effect with respect to the transistor 701 can be neglected if the fluctuations affect the internal power supply voltage DVDD a little. In other words, the same effect can be obtained irrespective of the presence or absence of the back gate voltage effect with respect to the transistor 701.

What is claimed is:

1. An internal power supply voltage generation circuit for generating an internal power supply voltage from a power supply voltage input to a power supply terminal and supplying the internal power supply voltage to a logic circuit, the internal power supply voltage generation circuit comprising:
an output transistor for generating an output voltage which follows a voltage applied to an input of the output transistor; and
a voltage source provided to the input of the output transistor,
wherein the internal power supply voltage is given based on a sum of an absolute value of a threshold voltage of an N-type transistor and an absolute value of a threshold voltage of a P-type transistor, the N-type transistor and the P-type transistor forming the voltage source.

2. An internal power supply voltage generation circuit according to claim 1, wherein the N-type transistor and the P-type transistor forming the voltage source are formed in the same manufacturing process as respective transistors forming the logic circuit.

3. An internal power supply voltage generation circuit according to claim 1, wherein the output transistor comprises a MOS transistor.

4. An internal power supply voltage generation circuit according to claim 1, wherein the output transistor comprises a bipolar transistor.
